(19) United States
(12) Patent Application Publication
(10) Pub. No.: US 2022/0007533 A1
(43) Pub. Date: Jan. 6, 2022

(54) COVERS FOR ELECTRONIC DEVICES

(71) Applicant: Hewlett-Packard Development Company, L.P., Spring, TX (US)

(72) Inventors: Kuan-Ting Wu, Taipei (TW); Chi Hao Chang, Taipei (TW); Chalam Kashyap, Fort Collins, CO (US)

(73) Assignee: Hewlett-Packard Development Company, L.P., Spring, TX (US)

(21) Appl. No.: 17/054,562

(22) PCT Filed: Mar. 28, 2019
(86) PCT No.: PCT/US2019/024526

§ 371 Date: Nov. 11, 2020

(51) Int. Cl. H05K 5/04; C25D 11/02; C25D 13/04; C25D 13/12; C25D 13/20; B32B 15/08; B32B 3/02

(52) U.S. Cl. CPC H05K 5/04; B32B 2457/00; C25D 13/04; C25D 13/12; C25D 13/20; B32B 15/08; B32B 3/02; B32B 2250/02; B32B 2255/06; B32B 2255/10; B32B 2255/20; B32B 2255/26; B32B 2255/28; B32B 2307/4023; B32B 2451/00; C25D 11/026

(57) ABSTRACT

The present disclosure is drawn to covers for electronic devices, methods of making the covers, and electronic devices. In one example, a cover for an electronic device comprising: a metal cover substrate; a micro-arc oxidation layer or a non-transparent passivation treatment layer on a surface of the metal cover substrate; an outmold decoration layer on the micro-arc oxidation layer or the non-transparent passivation treatment layer, a chamfered edge including a chamfer at an edge of the metal cover substrate, wherein the chamfer cuts through the micro-arc oxidation layer or the non-transparent passivation treatment layer and the outmold decoration layer to expose the metal cover substrate at the chamfered edge; a transparent passivation layer on the chamfered edge where the metal cover substrate is exposed; and a protective coating on the transparent passivation layer.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market.

### BRIEF DESCRIPTION OF THE DRAWING

FIG. 1 is a cross-sectional view illustrating an example cover for an electronic device in accordance with examples of the present disclosure;

FIG. 2 is a cross-sectional view illustrating another example cover for an electronic device in accordance with examples of the present disclosure;

FIG. 3 is a flowchart illustrating an example method of making a cover for an electronic device in accordance with examples of the present disclosure; and

FIG. 4 is a flowchart illustrating another example method of making a cover for an electronic device in accordance with examples of the present disclosure.

### DETAILED DESCRIPTION

The present disclosure is drawn to covers for electronic devices, methods of making the covers, and electronic devices.

In some examples, described herein is a cover for an electronic device comprising: a metal cover substrate; a micro-arc oxidation layer or a non-transparent passivation treatment layer on a surface of the metal cover substrate; an outmold decoration layer on the micro-arc oxidation layer or the non-transparent passivation treatment layer; a chamfered edge including a chamfer at an edge of the metal cover substrate, wherein the chamfer cuts through the micro-arc oxidation layer or the non-transparent passivation treatment layer and the outmold decoration layer to expose the metal cover substrate at the chamfered edge; a transparent passivation layer on the chamfered edge where the metal cover substrate is exposed; and a protective coating on the transparent passivation layer.

In some examples, the metal cover substrate comprises aluminum, magnesium, lithium, titanium, zinc, niobium, stainless steel, or an alloy thereof.

In some examples, the micro-arc oxidation layer is formed by plasma electrolytic oxidation of the surface of the metal cover substrate.

In some examples, the non-transparent passivation treatment layer having a thickness of from about 1 to about 5 μm, and the non-transparent passivation treatment layer comprises molybdates, vanadates, phosphates, chromates, stannates, manganese salts, or combinations thereof.

In some examples, the protective coating is a paint coating comprising a colorant and a polymeric binder.

In some examples, the protective coating is an electrophoretic deposition coating comprising a polymer binder, a pigment, and a dispersant.

In some examples, the transparent passivation layer comprises a chelating agent and a metal ion, a chelated metal complex of the chelating agent and the metal ion, an oxide of the metal ion, or a combination thereof, wherein the metal ion is an aluminum ion, an indium ion, a nickel ion, a chromium ion, a tin ion, or a zinc ion.

In some examples, the outmold decoration layer comprises polyester, polyvinyl chloride, polyacrylic, polyurethane, silicone rubber, or combinations thereof.

In some examples, disclosed herein is an electronic device comprising the cover described above.

In some examples, described herein is a cover for an electronic device comprising: a metal cover substrate; a micro-arc oxidation layer or a non-transparent passivation treatment layer on a surface of the metal cover substrate; a primer coating layer on the micro-arc oxidation layer or on the non-transparent passivation treatment layer; an outmold decoration layer on the primer coating layer; a chamfered edge including a chamfer at an edge of the metal cover substrate, wherein the chamfer cuts through the micro-arc oxidation layer or the non-transparent passivation treatment layer, the primer coating layer, and the outmold decoration layer to expose the metal cover substrate at the chamfered edge; a transparent passivation layer on the chamfered edge where the metal cover substrate is exposed; and a protective coating on the transparent passivation layer.

In some examples, described herein is an electronic device comprising: an electronic component; and the cover described above.

In some examples, the electronic device is a laptop, tablet computer, smartphone, an e-reader, or a music player.

In some examples, the chamfered edge is located at an edge of a touchpad, an edge of a fingerprint scanner, an outer edge of the cover, an edge of a sidewall, or an edge of a logo.

In some examples, the cover comprises multiple chamfered edges with multiple protective coatings at different chamfered edges.

In some examples, described herein is a method of making a cover for an electronic device comprising: forming a micro-arc oxidation layer or a non-transparent passivation treatment layer on a surface of a metal cover substrate; applying an outmold decoration layer on the micro-arc oxidation layer or on the non-transparent passivation treatment layer; forming a chamfered edge at an edge of the metal cover substrate by the chamfer cutting through the micro-arc oxidation layer or the non-transparent passivation treatment layer and the outmold decoration layer to expose the metal cover substrate at the chamfered edge; forming a transparent passivation layer on the chamfered edge where the metal cover substrate is exposed; and applying a protective coating on the transparent passivation layer.

In some examples, the metal cover substrate comprises aluminum, magnesium, lithium, titanium, zinc, niobium, stainless steel, or an alloy thereof.

### Covers for Electronic Devices

The present disclosure describes covers for electronic devices that can be strong and lightweight and have a decorative appearance. In some cases, light metal materials can be used to make covers for electronic devices. Generally, light metals can include aluminum, magnesium, titanium, lithium, niobium, zinc, and alloys thereof. Covers can also be made from stainless steel in some cases. These materials can have useful properties, such as low weight, high strength, and an appealing appearance. However, some of these metals can be easily oxidized at the surface, and may be vulnerable to corrosion or other chemical reactions at the surface. For example, magnesium or magnesium alloys in particular can be used to form covers for electronic devices because of the low weight and high strength of magnesium. Magnesium can have a somewhat porous surface that can be vulnerable to chemical reactions and corrosion at the surface. In some examples, magnesium or magnesium alloy can be treated by micro-arc oxidation to form a layer of protective oxide at the surface. This protective oxide layer can increase the chemical resistance, hardness, and durability of the magnesium or magnesium alloy. However, micro-arc oxidation can also create a dull appearance instead of the original luster of the metal.

The present disclosure describes covers for electronic devices that can utilize the above metals for their favorable properties and at the same time the metals can be protected from corrosion. Furthermore, the covers can have an attractive appearance. In some cases, it can be desirable to chamfer certain edges of the cover for ergonomics and/or to enhance the appearance of the cover. Some examples of edges that may be chamfered can include an edge surrounding a track pad on a lap top, an edge surrounding a fingerprint scanner, an outer edge of a smartphone housing, and so on.

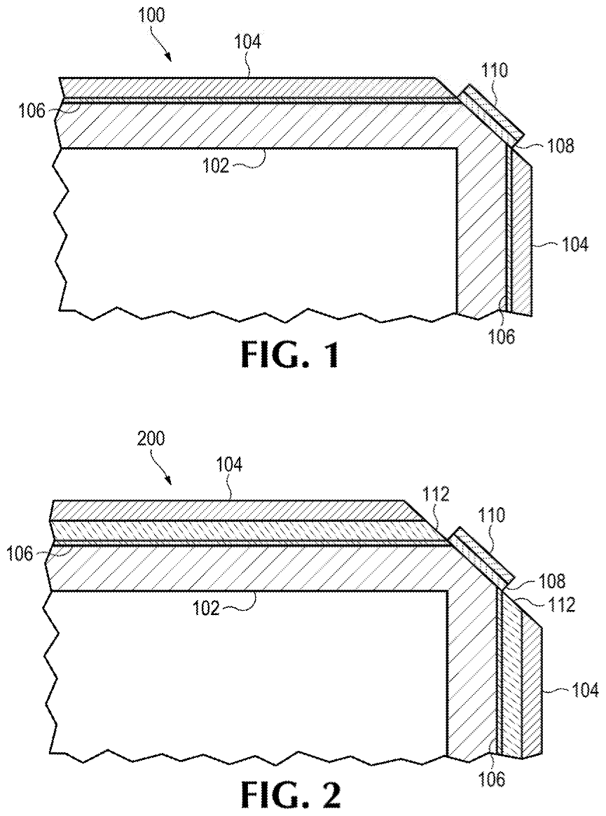

FIG. 1 shows an example cover 100 for an electronic device. The cover 100 comprises a metal cover substrate 102; a micro-arc oxidation layer or a non-transparent passivation treatment layer 106 on a surface of the metal cover substrate 102; an outmold decoration layer 104 on the micro-arc oxidation layer or the non-transparent passivation treatment layer 106; a chamfered edge including a chamfer at an edge of the metal cover substrate, wherein the chamfer cuts through the micro-arc oxidation layer or the non-transparent passivation treatment layer and the outmold decoration layer to expose the metal cover substrate at the chamfered edge; a transparent passivation layer 108 on the chamfered edge where the metal cover substrate is exposed; and a protective coating 110 on the transparent passivation layer.

FIG. 2 shows an example cover 200 for an electronic device. The cover 200 comprises a metal cover substrate 102; a micro-arc oxidation layer or a non-transparent passivation treatment layer 106 on a surface of the metal cover substrate; a primer coating layer 112 on the micro-arc oxidation layer or on the non-transparent passivation treatment layer; an outmold decoration layer 104 on the primer coating layer; a chamfered edge including a chamfer at an edge of the metal cover substrate, wherein the chamfer cuts through the micro-arc oxidation layer or the non-transparent passivation treatment layer, the primer coating layer, and the outmold decoration layer to expose the metal cover substrate at the chamfered edge; a transparent passivation layer 108 on the chamfered edge where the metal cover substrate is exposed; and a protective coating 110 on the transparent passivation layer.

As shown in FIGS. 1 and 2, in these examples edges of the covers are chamfered by cutting away material along a 90° angled edge at a 45° angle so that the 90° edge is replaced by a sloped surface at 45°. Accordingly, as used herein, “chamfer” refers to the action of cutting away an edge where two faces meet to form a sloping face transitioning between the two original faces. In some cases, the term “chamfered edge” can refer to the entire transition area between the original faces that metal at the edge before chamfering together with the sloped face created by the chamfering. In other cases, the term “chamfered edge” may refer specifically to the sloped face created by the chamfering. In many cases, the original edge can be a 90° angle edge, and the chamfer can create a sloping face at a 45° angle. However, in some examples the original edge can have a different angle and the chamfer can create a sloping surface with a different angle. In further examples, chamfering can be performed using a milling machine with a cutting bit oriented to cut away the edge and create the sloped surface of the chamfered edge. In other examples, the chamfer can be performed by laser cutting, water jet cutting, sanding, or any other suitable method.

Depending on the shape and design of a cover for an electronic device, the cover may have many different edges. Any of these edges can be chamfered depending on the desired final appearance of the cover. More particularly, in some examples the metal cover substrate (including either the entire substrate, a portion of the substrate, or multiples portions of the substrate) can be coated with a transparent passivation layer and/or a protective coating. Then any edge or multiple edges can be chamfered such that the chamfer cuts through the transparent passivation layer and/or the protective coating and exposes the metal cover substrate. In some examples, the chamfered edges can be treated with a passivation treatment to form a transparent passivation layer at the exposed metal cover substrate.

As used herein, “cover” refers to the exterior shell of an electronic device. In other words, the cover contains the internal electronic components of the electronic device. The cover is an integral part of the electronic device. The term “cover” is not meant to refer to the type of removable protective cases that are often purchased separately for an electronic device (especially smartphones and tablets) and placed around the exterior of the electronic device. Covers as described herein can be used on a variety of electronic devices. For example, laptop computers, smartphones, tablet computers, and other electronic devices can include the covers described herein. In various examples, the metal cover substrates for these covers can be formed by molding, casting, machining, bending, working, stamping, or another process. In one example, a metal cover substrate can be milled from a single block of metal. In other examples, the cover can be made from multiple panels. For example, laptop covers sometimes include four separate cover pieces forming the complete cover of the laptop. The four separate pieces of the laptop cover are often designated as cover A (back cover of the monitor portion of the laptop), cover B (front cover of the monitor portion), cover C (top cover of the keyboard portion) and cover D (bottom cover of the keyboard portion). Covers can also be made for smartphones and tablet computers with a single metal piece or multiple metal panels.

As used herein, a layer that is referred to as being “on” a lower layer can be directly applied to the lower layer, or an intervening layer or multiple intervening layers can be located between the layer and the lower layer. Generally, the covers described herein can include a metal cover substrate and a micro-arc oxidation layer or a non-transparent passivation treatment layer on a surface of the metal cover substrate. Accordingly, a layer that is “on” a lower layer can be located further from the metal cover substrate. However, in some examples there may be other intervening layers such as a primer coating layer underneath the micro-arc oxidation layer or the non-transparent passivation treatment layer. Thus, a “higher” layer applied “on” a “lower” layer may be located farther from the metal cover substrate and closer to a viewer viewing the cover from the outside.

It is noted that when discussing covers for electronic devices, the electronic devices themselves, or methods of making covers for electronic devices, such discussions can be considered applicable to one another whether or not they are explicitly discussed in the context of that example. Thus, for example, when discussing the metals used in the metal cover substrate in the context of one of the example covers, such disclosure is also relevant to and directly supported in the context of the electronic devices and/or methods, and vice versa. It is also understood that terms used herein will take on their ordinary meaning in the relevant technical field unless specified otherwise. In some instances, there are terms defined more specifically throughout or included at the end of the present disclosure, and thus, these terms are supplemented as having a meaning described herein.

### Electronic Devices

A variety of electronic devices can be made with the covers described herein. In various examples, such electronic devices can include various electronic components enclosed by the cover. As used herein, “encloses” or “enclosed” when used with respect to the covers enclosing electronic components can include covers completely enclosing the electronic components or partially enclosing the electronic components. Many electronic devices include openings for charging ports, input/output ports, headphone ports, and so on. Accordingly, in some examples the cover can include openings for these purposes. Certain electronic components may be designed to be exposed through an opening in the cover, such as display screens, keyboard keys, buttons, track pads, fingerprint scanners, cameras, and so on. Accordingly, the covers described herein can include openings for these components. Other electronic components may be designed to be completely enclosed, such as motherboards, batteries, sim cards, wireless transceivers, memory storage drives, and so on. Additionally, in some examples a cover can be made up of two or more cover sections, and the cover sections can be assembled together with the electronic components to enclose the electronic components. As used herein, the term “cover” can refer to an individual cover section or panel, or collectively to the cover sections or panels that can be assembled together with electronic components to make the complete electronic device.

In some examples, the electronic devices can be personal computers, laptops, tablet computers, e-readers, music players, smartphones, mouse, keyboards, or a variety of other types of electronic devices. In certain examples, the chamfered edge or edges can be located in decorative locations on the cover. Some examples include chamfered edges around track pads, around fingerprint scanners, at outer edges of the cover, at an edge of a sidewall, at an edge of a logo, and so on.

### Methods of Making Covers for Electronic Devices

In some examples, the covers described herein can be made by first forming the metal cover substrate. This can be accomplished using a variety of processes, including molding, forging, casting, machining, stamping, bending, working, and so on. The metal cover substrate can be made from a variety of metals. In certain examples, the metal cover substrate can include aluminum, magnesium, lithium, titanium, zinc, niobium, stainless steel, or an alloy thereof. As mentioned above, in some examples the metal cover substrate can be a single piece while in other examples the metal cover substrate can include multiple pieces that each make up a portion of the cover. Additionally, in some examples the metal cover substrate can be a composite made up of multiple metals combined, such as having layers of multiple different metals or panels or other portions of the metal cover substrate being different metals.

A micro-arc oxidation layer or a non-transparent passivation treatment layer can be applied to any surface of the metal cover substrate, including fully or partially covering a single surface, fully or partially covering multiple surfaces, or fully or partially covering the metal cover substrate as a whole. The micro-arc oxidation layer or the non-transparent passivation treatment layer can be applied by any suitable application method.

In some examples, an optional primer coating layer can be applied on the micro-arc oxidation layer or on the non-transparent passivation treatment layer. An outmold decoration layer can be applied on the optional primer coating layer or on the micro-arc oxidation layer or the non-transparent passivation treatment layer.

The chamfered edges can be formed on an edge of the metal cover substrate coated with the above-described layers. In various examples, chamfered edges can be formed at any edge or combination of edges on the cover. The chamfered edge can vary in depth. The term “depth” of chamfered edges refers to the amount of the edge that is cut away by the chamfering process. The depth of the chamfer can be stated in terms of the distance from the original edge of the cover to the edge of the sloped surface created by the chamfering. In various examples, the chamfer can be from about 0.1 mm to about 1 cm deep. In other examples, the chamfer can be from about 0.2 mm to about 5 mm deep. As stated above, in some examples the chamfer can be symmetrical so that the same amount of material is removed on both faces of the cover that meet at the chamfered edge. In a symmetrical chamfering of a 90° edge, the new sloped surface created by the chamfering is at a 45° angle with respect to the original faces of the cover. However, in other examples, the chamfer can be asymmetrical so that the angle of the sloped surface is different with respect to each of the original faces of the cover. The examples of the depth of the chamfer described above can refer to either side of the chamfer in the case of an asymmetrical chamfer.

The chamfered edge can be formed using any suitable process that can remove material at the edge of the cover and produce a sloped surface in place of the original edge. In some examples, the chamfer can be formed using a CNC machine such as a milling machine, a router, a laser cutter, a water jet cutter, a sander, a file, or other methods.

A transparent passivation can be formed on the exposed metal cover substrate after chamfering the edge. In some examples, this can be accomplished using a passivation treatment. Some passivation treatments may include immersing the cover in a passivation treatment bath, so that all surfaces of the cover are contacted by reagents for the passivation treatment. However, in some examples the passivation treatment may affect the exposed metal cover substrate while having no effect on the surfaces that are coated with the protective coating. Transparent passivation treatments can include treatments involving a chelating agent and a metal ion or a chelated metal complex, as described in more detail below. In some examples, a protective coating can be applied on the transparent passivation layer.

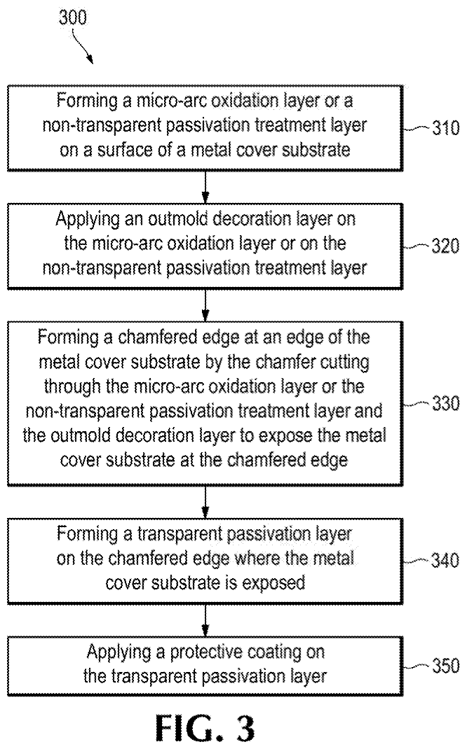

FIG. 3 is a flowchart illustrating an example method 300 of making a cover for an electronic device. The method comprises forming a micro-arc oxidation layer or a non-transparent passivation treatment layer on a surface of a metal cover substrate (310); applying an outmold decoration layer on the micro-arc oxidation layer or on the non-transparent passivation treatment layer (320); forming a chamfered edge at an edge of the metal cover substrate by the chamfer cutting through the micro-arc oxidation layer or the non-transparent passivation treatment layer and the outmold decoration layer to expose the metal cover substrate at the chamfered edge (330); forming a transparent passivation layer on the chamfered edge where the metal cover substrate is exposed (340); and applying a protective coating on the transparent passivation layer (350).

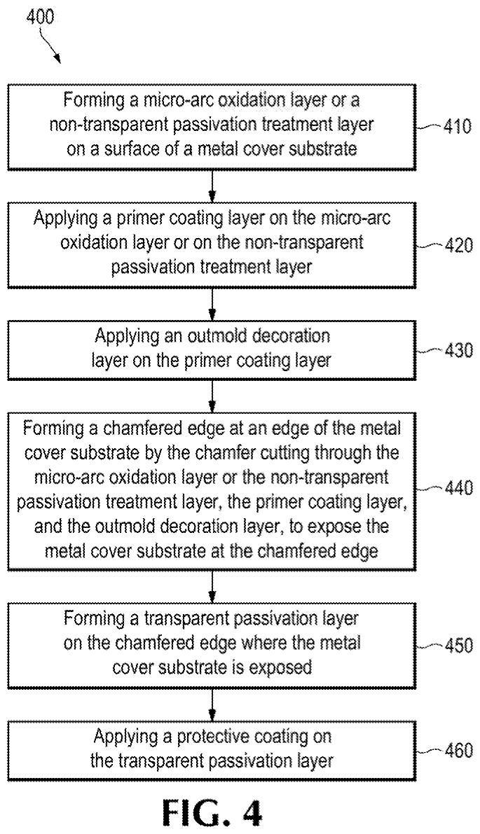

FIG. 4 is a flowchart illustrating an example method 400 of making a cover for an electronic device. The method comprises forming a micro-arc oxidation layer or a non-transparent passivation treatment layer on a surface of a metal cover substrate (410); applying a primer coating layer on the micro-arc oxidation layer or on the non-transparent passivation treatment layer (420); applying an outmold decoration layer on the primer coating layer (430); forming a chamfered edge at an edge of the metal cover substrate by the chamfer cutting through the micro-arc oxidation layer or the non-transparent passivation treatment layer, the primer coating layer, and the outmold decoration layer, to expose the metal cover substrate at the chamfered edge (440); forming a transparent passivation layer on the chamfered edge where the metal cover substrate is exposed (450); applying a protective coating on the transparent passivation layer (460).

### Metal Cover Substrate

In some examples, the metal cover substrate comprises aluminum, magnesium, lithium, titanium, zinc, niobium, stainless steel, or an alloy thereof.

The metal cover substrate can be made from a single metal, a metallic alloy, a combination of sections made from multiple metals, or a combination of metal and other materials. In some examples, the metal cover substrate can include a light metal. In certain examples, the metal cover substrate can include aluminum, magnesium, lithium, titanium, zinc, niobium, stainless steel, or an alloy thereof. In further particular examples, the metal cover substrate can include aluminum, an aluminum alloy, magnesium, or a magnesium alloy. Non-limiting examples of elements that can be included in aluminum or magnesium alloys can include aluminum, magnesium, titanium, lithium, niobium, zinc, bismuth, copper, cadmium, iron, thorium, strontium, zirconium, manganese, nickel, lead, silver, chromium, silicon, tin, gadolinium, yttrium, calcium, antimony, cerium, lanthanum, or others.

In some examples, the metal cover substrate can include an aluminum magnesium alloys made up of about 0.5% to about 13% magnesium by weight and 87% to 99.5% aluminum by weight. Examples of specific aluminum magnesium alloys can include 1050, 1060, 1199, 2014, 2024, 2219, 3004, 4041, 5005, 5010, 5019, 5024, 5026, 5050, 5052, 5056, 5059, 5083, 5086, 5154, 5182, 5252, 5254, 5356, 5454, 5456, 5457, 5557, 5652, 5657, 5754, 6005, 6005A, 6060, 6061, 6063, 6066, 6070, 6082, 6105, 6162, 6262, 6351, 6463, 7005, 7022, 7068, 7072, 7075, 7079, 7116, 7129, and 7178.

In further examples, the metal cover substrate can include magnesium metal, a magnesium alloy that is 99% or more magnesium by weight, or a magnesium alloy that is from about 50% to about 99% magnesium by weight. In a particular example, the metal cover substrate can include an alloy including magnesium and aluminum. Examples of magnesium-aluminum alloys can include alloys made up of from about 91% to about 99% magnesium by weight and from about 1% to about 9% aluminum by weight, and alloys made up of about 0.5% to about 13% magnesium by weight and 87% to 99.5% aluminum by weight. Specific examples of magnesium-aluminum alloys can include AZ63, AZ81, AZ91, AM50, AM60, AZ31, AZ61, AZ80, AE44, AJ62A, ALZ391, AMCa602, LZ91, and Magnox.

The metal cover substrate can be shaped to fit any type of electronic device, including the specific types of electronic devices described herein. In some examples, the metal cover substrate can have any thickness suitable for a particular type of electronic device. The thickness of the metal in the metal cover substrate can be selected to provide a desired level of strength and weight for the cover of the electronic device. In some examples, the metal cover substrate can have a thickness from about 0.3 mm to about 2 cm, or from about 0.5 mm to about 1.5 cm, or from about 1 mm to about 1.5 cm, or from about 1.5 mm to about 1.5 cm, or from about 2 mm to about 1 cm, or from about 3 mm to about 1 cm, or from about 4 mm to about 1 cm, or from about 1 mm to about 5 mm, though thicknesses outside of these ranges can be used.

In still further examples, the metal cover substrate can include a metal having a micro-arc oxidation layer on a surface thereof. Micro-arc oxidation, also known as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 1 wt % to about 5 wt % electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt % to about 3.5 wt %, or from about 2 wt % to about 3 wt %, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be about 200 V or higher, such as about 200 V to about 600 V, about 250 V to about 600 V, about 250 V to about 500 V, or about 200 V to about 300 V. Temperatures can be from about 20° C. to about 40° C., or from about 25° C. to about 35° C., for example, though temperatures outside of these ranges can be used. This process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 μm or more.

In some examples the oxide layer can have a thickness from about 1 μm to about 25 μm, from about 1 μm to about 22 μm, or from about 2 μm to about 20 μm. Thickness can likewise be from about 2 μm to about 15 μm, or from about 3 μm to about 10 μm, or from about 4 μm to about 7 μm. The oxide layer can, in some instances, enhance the mechanical, wear, thermal, dielectric, and corrosion properties of the substrate. The electrolyte solution can include a variety of electrolytes, such as a solution of potassium hydroxide. In some examples, the metal cover substrate can include a micro-arc oxidation layer on one side, or on both sides.

### Micro-Arc Oxidation Layer

In some examples, the micro-arc oxidation layer is formed by plasma electrolytic oxidation of the surface of the metal cover substrate.

In still further examples, the rigid substrate can include a metal having a micro-arc oxidation layer on a surface thereof. Micro-arc oxidation, also known as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 1 wt % to about 5 wt % electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt % to about 3.5 wt %, or from about 2 wt % to about 3 wt %, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be 200 V or higher, such as about 200 V to about 600 V, about 250 V to about 600 V, about 250 V to about 500 V, or about 200 V to about 300 V. Temperatures can be from about 20° C. to about 40° C., or from about 25° C. to about 35° C., for example, though temperatures outside of these ranges can be used.

The above process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 μm or more.

In some examples the oxide layer can have a thickness from about 1 μm to about 25 μm, from about 1 μm to about 22 μm, or from about 2 μm to about 20 μm. Thickness can likewise be from about 2 μm to about 15 μm, or from about 3 μm to about 10 μm, or from about 4 μm to about 7 μm.

The oxide layer can, in some instances, enhance the mechanical, wear, thermal, dielectric, and corrosion properties of the substrate. The electrolyte solution can include a variety of electrolytes, such as a solution of potassium hydroxide. In some examples, the rigid substrate can include a micro-arc oxidation layer on one side, or on both sides.

### Non-Transparent Passivation Treatment Layer

In some examples, the non-transparent passivation treatment layer having a thickness of from about 1 to about 5 μm, and the non-transparent passivation treatment layer comprises molybdates, vanadates, phosphates, chromates, stannates, manganese salts, or combinations thereof.

In some examples, a magnesium alloy metal cover substrate can be protected from corrosion by applying a passivation layer at a thickness from about 1 μm to about 5 μm to the magnesium alloy substrate, wherein the passivation layer includes a molybdate, a vanadate, a phosphate, a chromate, a stannate, or a manganese salt.

As used herein, “non-transparent” means opaque or substantially opaque or a layer or coating through which light is unable to pass through freely. The “non-transparent” passivation treatment layer described herein is a layer that is opaque or substantially opaque.

A magnesium alloy substrate may be treated with a non-transparent passivation layer to protect magnesium alloy from corrosion. The non-transparent passivation layer can include, for example, various passivation compounds, such a chromate, a phosphate, a molybdate, a vanadate, a stannate, a manganese salt, or a combination thereof. In some examples, a passivation treatment process to generate a non-transparent passivation layer can include dissolving or dispersing a passivating compound, such as one of the passivating compounds, in a solution and immersing the substrate in the solution to form a layer of the passivating compound on the substrate. The solution or dispersion of the passivating compound can include the passivating compound, for example, at from about 1 wt % to about 10 wt %, from about 1.5 wt % to about 7.5 wt %, or from about 2 wt % to about 5 wt %. Examples of passivation treatment processes that generate conversion coatings by this or other similar processes can include processes that generate a chromate conversion coating, a phosphate conversion coating, a molybdate conversion coating, a vanadate conversion coating, a stannate conversion coating, manganese salt conversion coating, etc. In some examples, the substrate can be passivated on one side, or on both sides.

In some examples, the passivation layer can have a thickness from about 1 μm to about 5 μm, or from about 2 μm to about 4 μm, or about 3 μm. The non-transparent passivation layer can, in some instances, improve the mechanical, wear, thermal, dielectric, and corrosion properties of the substrate.

### Primer Coating Layer

A primer layer can be added to the surface of the rigid substrate before adhering the outmold decoration layer. The substrate primer layer can increase adhesion of the outmold decoration layer to the substrate. In a particular example, a primer coating layer can be applied over a micro-arc oxidation layer or a non-transparent passivation treatment layer on a metal substrate to increase the adhesion between the outmold decoration layer and the micro-arc oxidation layer or the non-transparent passivation treatment layer. In another example, a primer coating layer can be applied over a micro-arc oxidation layer or a non-transparent passivation treatment layer.

In some examples, the primer coating layer can increase adhesion and also fill in any gaps or uneven surfaces. In some examples, the primer coating layer can include a polyurethane or polyurethane copolymer. In certain examples, the polyurethane or polyurethane copolymer can be formed by polymerizing a polyisocyanate and a polyol. Non-limiting examples of polyisocyanates that can be used include toluene diisocyanate, methylene diphenyl diisocyanate, 1,6-hexamethylene diisocyanate, isophorone diisocyanate, 4,4′-diisocyanato dicyclohexylmethane, trimethylhexamethylene diisocyanate, and others. The polyol can, in some examples, be a polyether polyol or a polyester polyol having a weight average molecular weight from about 100 to about 10,000 or from about 200 to about 5,000. In certain examples, the polyol can be a diol that includes two hydroxyl groups.

In further examples, the primer coating layer can have a thickness from about 1 μm to about 50 μm, or from about 2 μm to about 25 μm, or from about 5 μm to about 15 μm.

In certain examples, the primer coating layer can include a moisture-cured polyurethane. Moisture-cured polyurethanes can include isocyanate-terminated prepolymers that can be cured with ambient water. In an example, the primer can include Airethane™ 1204 polyurethane or other Airethane™ 1000 series polyurethanes (Fairmont Industries). In other examples, the primer coating layer can include an alkyd resin. Alkyd resins are thermoplastic resins made from polyhydric alcohols and polybasic acids or their anhydrides. In some examples, alkyd resins can be made by a polycondensation reaction of a polyol with a dicarboxylic acid or its anhydride. Non-limiting examples of other polybasic acids that can be used in alkyd resins include phthalic anhydride, isophthalic anhydride, maleic anhydride, fumaric acid, and others. Non-limiting examples of polyols that can be used in alkyd resins include glycerol, trimethylolethane, trimethylolpropane, pentaerythritol, ethylene glycol, and neopentyl glycol. In some examples, a monobasic acid can also be included in the reaction to modify the alkyd resin. In specific examples, the primer can include a resin from the DOMALKYD™ line of resins, such as DOMALKYD™ 4161 (Helios).

### Outmold Decoration Layer

In some examples, the outmold decoration layer comprises polyester, polyvinyl chloride, polyacrylic, polyurethane, silicone rubber, or combinations thereof.

The outmold decoration layers described herein can be adhered to the micro-arc oxidation layer or the non-transparent passivation treatment layer to give the covers of electronic devices a particular decorative appearance and/or tactile texture. In some examples, the outmold decoration layers can be designed to have a sparkling or metallic appearance. In various examples the appearance can be partially obtained by using sparkling pigments, metal powders, non-conductive vacuum metallization, or other such materials in the decorative films. Additionally, the outmold decoration layers can include a clear top coat layer with a molded three dimensional pattern on the top surface. The molded three dimensional pattern can provide a specific tactile texture to the film and can also contribute to the decorative appearance of the film. In some examples, the three dimensional pattern can be designed to utilize the reflection and refraction of light by the clear top coat to contribute to the sparkling or metallic appearance of the film. For example, the three dimensional pattern can include multiple facets oriented at different angles to reflect and refract light to create a specific desired appearance.

In further examples, the outmold decoration layers can provide a desired appearance to a cover for an electronic device without interfering with radio wave transmission to or from the electronic device. Many electronic devices include transceivers for sending and receiving radio waves to cellular networks, Wi-Fi routers, wireless accessories, and so on. Some materials can block or interfere with these radio waves. In particular, metal enclosures can often block incoming and outgoing radio waves. The outmold decoration layers described herein can provide a desired appearance, including a metallic appearance, without blocking radio waves. In some examples, the outmold decoration layers can include a non-conductive vacuum metallized layer that has a metallic appearance, but which does not block the radio waves.

The outmold decoration layers described herein can be produced by efficient manufacturing processes such as roll-to-roll process, out molding process, or combinations thereof. In certain examples, a roll-to-roll process can be used to add the various layers of materials to the film. The three dimensional molded pattern can be molded into the clear top coat layer by a patterned roller, for example.

In some examples, the outmold decoration layers can have a thickness of from about 1 μm to about 25 μm, or from about 5 μm to about 20 μm, or from about 10 μm to about 15 μm, or less than about 30 μm, or less than about 25 μm, or less than about 20 μm, or less than about 15 μm.

### Transparent Passivation Layers

In some examples, the transparent passivation layer comprises a chelating agent and a metal ion, a chelated metal complex of the chelating agent and the metal ion, an oxide of the metal ion, or a combination thereof, wherein the metal ion is an aluminum ion, an indium ion, a nickel ion, a chromium ion, a tin ion, or a zinc ion.

In some examples, a passivation treatment can be used to form a transparent passivation layer at the metal cover substrate exposed at the chamfered edge. It is noted that the transparent passivation layer is described as a layer for convenience, and thus, can be in the form of a layer. However, the term “passivation layer” also includes metal surface treatment of the exposed metal substrate. In some sense, it may not be a discrete layer that is applied similarly to that of a coating or a paint, for example, but can become infused or otherwise become part of the metal substrate at or near a surface of the chamfered edge. In some examples, the transparent passivation layer can include a chelating agent and a metal ion or a chelated metal complex thereof, wherein the metal ion is an aluminum ion, an indium ion, a nickel ion, a chromium ion, a tin ion, or a zinc ion. In certain examples, passivation treatment can be applied at a pH from about 2 to about 5. In a particular example, the pH can be about 2.5 to about 3.5.

In further examples, the transparent passivation layer can include an oxide of one of these metals. In some cases, various contaminants can be present on the surface of the metal cover substrate. The chelating agent can chelate such contaminants and prevent the contaminants from attaching to the surface of the metal cover substrate. Non-limiting examples of chelating agents can include ethylenediaminetetraacetic acid, ethylenediamine, nitrilotriacetic acid, diethylenetriaminepenta(methylenephosphonic acid), nitilotris(methylenephosphonic acid) and 1-hydroxyethane-1,1-disphosphonic acid. At the same time, a passivating metal oxide layer may form on the surface of the metal cover substrate.

In some examples, the transparent passivation layer can have a thickness from about 10 nm to about 3 μm, or from about 50 nm to about 1 μm, or from about 100 nm to about 1000 nm, or from about 200 nm to about 900 m, or from about 300 nm to about 800 nm, or from about 400 nm to about 700 nm.

In certain examples, the transparent passivation can be added to the pre-existing surface of the metal cover substrate, such that the transparent passivation layer includes additional material added onto the surface of the metal cover substrate. In other examples, the passivation layer can involve converting the existing surface of the metal cover substrate into a passive layer so that no net addition of material to the pre-existing surface occurs.

### Protective Coating

In some examples, the protective coating is a paint coating comprising a colorant and a polymeric binder. In some examples, the protective coating is an electrophoretic deposition coating comprising a polymer binder, a pigment, and a dispersant.

In some examples, a protective coating layer can be applied over the metal cover substrate. In a certain example, the protective coating layer can include a polymer resin. In certain examples, the polymer resin can be transparent and the protective coating layer can be a clear coat layer that allows the color of the underlying materials to show through. In further examples, the protective coating may be colored. In a particular example, the protective coating can include a layer of colored coating and a layer of clear coating on the colored coating. In some examples, the polymer resin of the clear coat layer can be clear poly(meth)acrylic, clear polyurethane, clear urethane (meth)acrylate, clear (meth)acrylic (meth)acrylate, or clear epoxy (meth)acrylate coating.

In further examples, the protective coating can include fillers such as pigment dispersed in an organic polymer resin. Non-limiting examples of pigments used in the protective coating layer can include carbon black, titanium dioxide, clay, mica, talc, barium sulfate, calcium carbonate, synthetic pigment, metallic powder, aluminum oxide, graphene, pearl pigment, or a combination thereof. The pigment can be present in the protective coating layer in an amount from about 0.5 wt % to about 30 wt % with respect to dry components of the protective coating layer, in some examples. In other examples, the amount of pigment can be from about 1 wt % to about 25 wt % or from about 2 wt % to about 15 wt % with respect to dry components of the protective coating layer.

The polymer resin included in the protective coating layer with the pigment can include polyester, poly(meth)acrylic, polyurethane, epoxy, urethane (meth)acrylic, (meth)acrylic (meth)acrylate, epoxy (meth)acrylate, or a combination thereof. As used herein, a “combination” of multiple different polymers can refer to a blend of homopolymers, a copolymer made up of the different polymers or monomers thereof, or adjacent layers of the different polymers. In certain examples, the polymer resin of the protective coating layer can have a weight-average molecular weight from about 100 g/mol to about 6,000 g/mol.

The thickness of the protective coating layer can be from about 5 μm to about 100 μm in some examples. In further examples, the thickness can be from about 10 μm to about 25 μm, or less than about 100 μm, or less than about 90 μm, or less than about 80 μm, or less than about 70 μm, or less than about 60 μm, or less than about 50 μm, or less than about 40 μm, or less than about 30 μm, or less than about 20 μm, or less than about 15 μm, or less than about 10 μm.

In certain examples, the protective coating layer can include a base coat that is colored and a top coat that is clear. Thus, the colored layer and the clear coat layer described above can be used together in certain examples. The overall thickness of the base coat with the top coat can be from about 2 μm to about 100 μm, or from about 5 μm to about 60 μm, or from about 10 μm to about 40 μm, in some examples.

In further examples, the colored protective coating layer, the top clear coat layer, or both, can be radiation curable. The polymer resin used in these layers can be curable using heat and/or radiation. For example, a heat curing polymer resin can be used and then cured in an oven for a sufficient curing time. A radiation curing polymer resin can be exposed to sufficient radiation energy to cure the polymer resin. The protective coating layer can be cured after applying the layer to the cover. In certain examples, curing can include heating the protective coating layer at a temperature from about 50° C. to about 80° C., or from about 50° C. to about 60° C., or from about 60° C. to about 80° C. The layer can be heated for a curing time from about 5 minutes to about 40 minutes, or from about 5 minutes to about 10 minutes, or from about 20 minutes to about 40 minutes. In other examples, curing can include exposing the layer to radiation energy at an intensity from about 500 mJ/cm² to about 2,000 mJ/cm² or from about 700 mJ/cm² to about 1,300 mJ/cm². The layer can be exposed to the radiation energy for a curing time from about 5 seconds to about 30 seconds, or from about 10 seconds to about 30 seconds.

In other examples the protective coating can be an electrophoretic coating. The electrophoretic coating can include a polymeric binder, a pigment, and a dispersant. The electrophoretic coating process can sometimes be referred to as “electropainting” or “electrocoating” because of the use of electric current in the process. To deposit an electrophoretic coating on the cover of the electronic device, the metal cover substrate can be placed in a coating bath. The coating bath can include a suspension of particles including the polymeric binder, pigment, and dispersant. In certain examples, the solids content of the coating bath can be from about 3 wt % to about 30 wt % or from about 5 wt % to about 15 wt %. The metal cover substrate can be electrically connected to an electric power source. The metal cover substrate can act as one electrode and the power source can also be attached to a second electrode that is also in contact with the coating bath. An electric current can be run between the metal cover substrate and the second electrode. In certain examples, the electric current can be applied at a voltage from about 30 V to about 150 V. The electric current can cause the particles suspended in the coating bath to migrate to the surface of the metal cover substrate and coat the surface. After this deposition process, additional processing may be performed such as rinsing the metal cover substrate, baking the coated substrate to harden the coating, or exposing the coated substrate to radiation to cure radiation curable polymeric binders.

In some examples, electrophoretic coatings can include the same pigments and polymeric binders or resins described above in the paint-type protective coating. The thickness of the coating can also be in the same ranges described above.

### Definitions

It is noted that, as used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 5% or other reasonable added range breadth of a stated value or of a stated limit of a range. The term “about” when modifying a numerical range is also understood to include the exact numerical value indicated, e.g., the range of about 1 wt % to about 5 wt % includes 1 wt % to 5 wt % as an explicitly supported sub-range.

As used herein, “liquid vehicle” or “ink vehicle” refers to a liquid fluid in an ink. A wide variety of ink vehicles may be used with the systems and methods of the present disclosure. Such ink vehicles may include a mixture of a variety of different agents, including, surfactants, solvents, co-solvents, anti-kogation agents, buffers, biocides, sequestering agents, viscosity modifiers, surface-active agents, water, etc.

As used herein, “colorant” can include dyes and/or pigments.

As used herein, “dye” refers to compounds or molecules that absorb electromagnetic radiation or certain wavelengths thereof. Dyes can impart a visible color to an ink if the dyes absorb wavelengths in the visible spectrum.

As used herein, “pigment” generally includes pigment colorants, magnetic particles, aluminas, silicas, and/or other ceramics, organo-metallics or other opaque particles, whether or not such particulates impart color. Thus, though the present description primarily exemplifies the use of pigment colorants, the term “pigment” can be used more generally to describe pigment colorants and other pigments such as organometallics, ferrites, ceramics, etc. In one specific example, however, the pigment is a pigment colorant

As used herein, a plurality of items, structural elements, compositional elements, and/or materials may be presented in a common list for convenience. However, these lists should be construed as though the individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also to include all the individual numerical values or sub-ranges encompassed within that range as if individual numerical values and sub-ranges are explicitly recited. For example, a layer thickness from about 0.1 μm to about 0.5 μm should be interpreted to include the explicitly recited limits of 0.1 μm to 0.5 μm, and to include thicknesses such as about 0.1 μm and about 0.5 μm, as well as subranges such as about 0.2 μm to about 0.4 μm, about 0.2 μm to about 0.5 μm, about 0.1 μm to about 0.4 μm etc.

The following illustrates an example of the present disclosure. However, it is to be understood that the following is illustrative of the application of the principles of the present disclosure. Numerous modifications and alternative compositions, methods, and systems may be devised without departing from the spirit and scope of the present disclosure. The appended claims are intended to cover such modifications and arrangements.

What is claimed is:

1. A cover for an electronic device comprising:
a metal cover substrate;
a micro-arc oxidation layer or a non-transparent passivation treatment layer on a surface of the metal cover substrate;
an outmold decoration layer on the micro-arc oxidation layer or the non-transparent passivation treatment layer;
a chamfered edge including a chamfer at an edge of the metal cover substrate, wherein the chamfer cuts through the micro-arc oxidation layer or the non-transparent passivation treatment layer and the outmold decoration layer to expose the metal cover substrate at the chamfered edge;
a transparent passivation layer on the chamfered edge where the metal cover substrate is exposed; and
a protective coating on the transparent passivation layer.

2. The cover of claim 1, wherein the metal cover substrate comprises aluminum, magnesium, lithium, titanium, zinc, niobium, stainless steel, or an alloy thereof.

3. The cover of claim 2, wherein:
the micro-arc oxidation layer is formed by plasma electrolytic oxidation of the surface of the metal cover substrate; or
the non-transparent passivation treatment layer having a thickness of from about 1 to about 5 μm, and the non-transparent passivation treatment layer comprises molybdates, vanadates, phosphates, chromates, stannates, manganese salts, or combinations thereof.

4. The cover of claim 1, wherein the protective coating is a paint coating comprising a colorant and a polymeric binder.

5. The cover of claim 1, wherein the protective coating is an electrophoretic deposition coating comprising a polymer binder, a pigment, and a dispersant.

6. The cover of claim 1, wherein the transparent passivation layer comprises a chelating agent and a metal ion, a chelated metal complex of the chelating agent and the metal ion, an oxide of the metal ion, or a combination thereof, wherein the metal ion is an aluminum ion, an indium ion, a nickel ion, a chromium ion, a tin ion, or a zinc ion.

7. The cover of claim 1, wherein the outmold decoration layer comprises polyester, polyvinyl chloride, polyacrylic, polyurethane, silicone rubber, or combinations thereof.

8. An electronic device comprising the cover of claim 1.

9. A cover for an electronic device comprising:
a metal cover substrate;
a micro-arc oxidation layer or a non-transparent passivation treatment layer on a surface of the metal cover substrate;
a primer coating layer on the micro-arc oxidation layer or on the non-transparent passivation treatment layer;
an outmold decoration layer on the primer coating layer;
a chamfered edge including a chamfer at an edge of the metal cover substrate, wherein the chamfer cuts through the micro-arc oxidation layer or the non-transparent passivation treatment layer, the primer coating layer, and the outmold decoration layer to expose the metal cover substrate at the chamfered edge;
a transparent passivation layer on the chamfered edge where the metal cover substrate is exposed; and
a protective coating on the transparent passivation layer.

10. An electronic device comprising: an electronic component; and the cover of claim 1.

11. The electronic device of claim 10, wherein the electronic device is a laptop, tablet computer, smartphone, an e-reader, or a music player.

12. The electronic device of claim 10, wherein the chamfered edge is located at an edge of a touchpad, an edge of a fingerprint scanner, an outer edge of the cover, an edge of a sidewall, or an edge of a logo.

13. The electronic device of claim 10, wherein the cover comprises multiple chamfered edges with multiple protective coatings at different chamfered edges.

14. A method of making a cover for an electronic device comprising:
forming a micro-arc oxidation layer or a non-transparent passivation treatment layer on a surface of a metal cover substrate;
applying an outmold decoration layer on the micro-arc oxidation layer or on the non-transparent passivation treatment layer;
forming a chamfered edge at an edge of the metal cover substrate by the chamfer cutting through the micro-arc oxidation layer or the non-transparent passivation treatment layer and the outmold decoration layer to expose the metal cover substrate at the chamfered edge;
forming a transparent passivation layer on the chamfered edge where the metal cover substrate is exposed; and
applying a protective coating on the transparent passivation layer.

15. The method of claim 14, wherein the metal cover substrate comprises aluminum, magnesium, lithium, titanium, zinc, niobium, stainless steel, or an alloy thereof.
